(19) United States
(12) Patent Application Publication
(10) Pub. No.: US 2022/0123095 A1
(43) Pub. Date: Apr. 21, 2022

(54) OLED DISPLAY SUBSTRATE AND MANUFACTURING METHOD THEREOF, AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventor: Leilei CHENG, Beijing (CN)

(21) Appl. No.: 17/433,210

(22) PCT Filed: Feb. 3, 2021
(86) PCT No.: PCT/CN2021/075022

§ 371 Date: Aug. 23, 2021

(30) Foreign Application Priority Data
Feb. 6, 2020 (CN) 202010081411.3

(51) Int. Cl. H01L 27/32; H01L 51/52; H01L 51/56

(52) U.S. Cl. CPC H01L 27/3276; H01L 2227/323; H01L 51/56; H01L 51/5284

(57) ABSTRACT

The present disclosure provides an OLED display substrate, a manufacturing method thereof, and a display device, which relates to the field of display technologies. The OLED display substrate includes a light-shielding layer, a buffer layer, an active layer pattern, a gate insulating layer, a gate layer pattern, an interlayer insulating layer, a source-drain layer pattern, an anode, a light-emitting layer, and a cathode which are arranged in turn on a base substrate, wherein the source-drain layer pattern and/or the gate layer pattern are made of a transparent conductive material.

### CROSS-REFERENCE TO RELATED APPLICATIONS

The present application claims priority to Chinese Patent Application No. 202010081411.3 filed on Feb. 6, 2020 in China, which is incorporated herein by reference in its entirety.

### TECHNICAL FIELD

The present disclosure relates to the technical field of displays, and particularly relates to an OLED display substrate, a manufacturing method thereof, and a display device.

### BACKGROUND

OLED (organic light-emitting diode) display devices have gradually become the mainstream of a display industry because of their high contrast, self-light-emitting and other advantages.

With the increasing demand for display, a high-revolution display technology has been paid more and more attention. In high-PPI (pixel density) OLED display devices, in order to reduce voltage drop on circuits, it is required to use double-layer metal wiring to reduce the impedance of the wiring, so as to reduce the voltage drop on the circuits and reduce the power consumption; in addition, it is required to form a storage capacitor by using a metal pattern that shields a thin film transistor, which results in a higher density of the metal pattern in the OLED display devices, so that the pixel light-emitting area is limited to the metal pattern with a lower aperture ratio.

### SUMMARY

Embodiments of the present disclosure provide technical solutions as follows:

according to a first aspect of the present disclosure, an OLED display substrate is provided, including an active layer pattern, a gate layer pattern, a source-drain layer pattern, an anode, a light-emitting layer and a cathode arranged in turn on a base substrate, wherein the source-drain layer pattern includes a source electrode, a drain electrode of the thin film transistor, and a data line, and the gate layer pattern includes a gate electrode of the thin film transistor and a gate line, wherein the source-drain layer pattern and/or the gate layer pattern are made of a transparent conductive material.

Optionally, the active layer pattern includes a first semiconductor sub-pattern and a second active layer sub-pattern, wherein the second active layer sub-pattern is subjected to a conductive treatment, the source-drain layer pattern further includes a signal line connected to the anode, an overlapping area exists between a orthographic projection of the second active layer sub-pattern on the base substrate and the orthographic projection of the signal line on the base substrate, and the second active layer sub-pattern is connected with the signal line in parallel through a plurality of through holes.

Optionally, the second active layer sub-pattern is in direct contact with the signal line.

Optionally, the active layer pattern includes a third active layer sub-pattern, wherein the third active layer sub-pattern is subjected to the conductive treatment, the source-drain layer pattern further includes a storage capacitor plate; an overlapping area exists between the orthographic projection of the third active layer sub-pattern on the base substrate and the orthographic projection of the storage capacitor plate on the base substrate; and the third active layer sub-pattern and the storage capacitor plate constitute a first storage capacitor of the OLED display substrate.

Optionally, the storage capacitor plate is made of an ITO or an IZO material.

Optionally, an overlapping area exists between a orthographic projection of the anode on the base substrate and a orthographic projection of the storage capacitor plate on the base substrate, the storage capacitor plate and the anode constitute a second storage capacitor of the OLED display substrate.

Optionally, the active layer pattern includes the first semiconductor sub-pattern and the second active layer sub-pattern, the orthographic projection of the light-shielding layer on the base substrate is located within the orthographic projection of the first semiconductor sub-pattern on the base substrate.

Optionally, the source-drain layer pattern includes the signal line connected to the anode, and the gate layer pattern includes the first gate layer sub-pattern and the second gate layer sub-pattern other than the first gate layer sub-pattern, wherein an overlapping area exists between the first gate electrode layer sub-pattern and the orthographic projection of the signal line on the base substrate, and the first gate electrode layer sub-pattern and the signal line are connected in parallel via the plurality of through holes, and the thickness of the first gate layer sub-pattern is less than the thickness of the second gate layer sub-pattern.

Optionally, the source-drain layer pattern includes the signal line connected to the anode, the light-shielding layer includes a first light-shielding sub-pattern, an overlapping area exists between the first light-shielding sub-pattern and the orthographic projection of the signal line on the base substrate, and the first light-shielding sub-pattern is connected to the signal line in parallel via the plurality of through holes.

Embodiments of the present disclosure also provide the display device including the OLED display substrate as described above.

The embodiments of the present disclosure also provide a method for manufacturing the OLED display substrate, which is used for manufacturing the OLED display substrate as described above, the OLED display substrate includes an active layer pattern, a gate layer pattern, a source-drain layer pattern, an anode, a light-emitting layer, and a cathode on a substrate which are formed in turn, wherein the source-drain layer pattern and/or the gate layer pattern are made of the transparent conductive material.

Optionally, before forming the active layer pattern, the manufacturing method further includes:

forming a light-shielding layer on the base substrate; forming a buffer layer.

Optionally, the manufacturing method further includes:

forming the active layer pattern on the base substrate, including forming the first semiconductor sub-pattern, the second active layer sub-pattern, and a third active layer sub-pattern;

forming a gate insulating layer pattern and a gate layer pattern;

performing the conductive treatment on the second active layer sub-pattern and the third active layer sub-pattern by using the gate layer pattern as a mask;

forming an interlayer insulating layer;

patterning a layer of transparent conductive material to form the source-drain, the storage capacitor plate, and the signal line; and

forming a protective insulating layer.

Optionally, the manufacturing method further includes:

forming the anode by patterning the layer of transparent conductive material;

forming a light-emitting layer on the anode by using an ink-jet printing technique;

forming a transparent cathode on the light-emitting layer; and

forming an encapsulation layer on the transparent cathode.

### BRIEF DESCRIPTION OF THE DRAWINGS

FIG. 1 is a schematic diagram of a related art OLED display substrate including a segment gap;

FIGS. 2-4 are schematic diagrams of forming a double layer wiring according to embodiments of the present disclosure;

FIG. 5 is a schematic diagram of a film layer of an OLED display substrate in the area of a thin film transistor according to embodiments of the present disclosure;

FIG. 6 is a schematic diagram of a film layer of an OLED display substrate in a storage capacitor area according to embodiments of the present disclosure; and

FIG. 7 is a schematic diagram of a film layer of an OLED display substrate in a double layer wiring area according to embodiments of the present disclosure.

### DETAILED DESCRIPTION

In order to make the technical problems, technical solutions, and advantages of the present disclosure clearer, a detailed description will be given below with reference to the accompanying drawings and specific embodiments.

In the related art, a non-transparent metal such as copper or aluminium is usually used to prepare a source-drain metal layer pattern and/or a gate metal layer pattern, so that a pixel light-emitting area is limited by a metal wiring and a small aperture opening ratio; in addition, a light-shielding layer is also used to form the storage capacitor, which requires a relatively larger area design of the light-shielding layer, further limiting the pixel aperture ratio; and in addition, in order to reduce the voltage drop on the circuit, using the gate metal layer and the source-drain metal layer to manufacture the double-layer wiring, in order to ensure signal transmission, the greater the resolution of the OLED display device, the higher the wiring density of the gate metal layer and the source-drain metal layer, resulting in a smaller pixel aperture opening ratio.

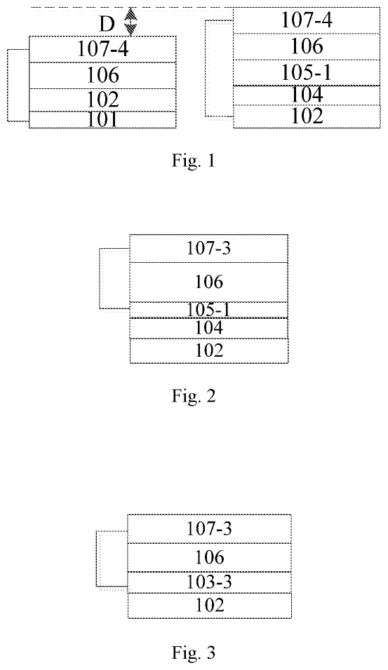

As shown in FIG. 1, in the OLED display substrate of the related art, a gate layer pattern 105-1 made of a metal and a signal line 107-4 made of the metal are used to form the double-layer wiring in a double-layer wiring area shown on the right side of FIG. 1 so as to reduce the resistance of the wiring; the thickness of the metal used for the gate layer pattern 105-1 and the signal line 107-4 is relatively large, and the thickness can reach 400-800 nm respectively; the number of film layers in the double-layer wiring area on the right side of FIG. 1 is different from that in the other areas shown on the left side of FIG. 1; and as a result of the large segment gap D existing on the surface of the OLED display substrate, the film layers with different planes are easily to form different sizes during exposure and development, which affects the contact resistance and overlap, and thus affect the product quality.

Embodiments of the present disclosure provide the OLED display substrate and the manufacturing method thereof, and the display device which can improve the pixel aperture opening ratio of an OLED display product and reduce a film segment gap of the OLED display substrate.

The embodiments of the present disclosure provide the OLED display substrate, including the active layer pattern, the gate layer pattern, the source-drain layer pattern, the anode, the light-emitting layer, and the cathode which are arranged in turn on the base substrate, wherein the source-drain layer pattern includes at least the source of the thin film transistor, a drain electrode, and a data line, wherein the gate layer pattern includes at least the gate electrode and a gate line of he thin film transistor, wherein the source-drain layer pattern and/or the gate layer pattern are made of the transparent conductive material.

In the present embodiment, the source-drain layer pattern can be made of the transparent conductive material, or the gate layer pattern can be made of the transparent conductive material, or both the source-drain layer pattern and the gate layer pattern can be made of the transparent conductive material. Compared with using the non-transparent metal for manufacturing the source-drain layer pattern and/or the gate layer pattern, the metal wiring density can be greatly reduced, so that a top-emitting OLED display device or a bottom-emitting OLED display device with a high aperture opening ratio can be manufactured, and even a transparent display device can be formed.

The base substrate can be a rigid transparent substrate or a flexible transparent substrate, and the transparent conductive material can specifically be ITO or IZO. The source-drain layer pattern includes patterns such as a source electrode, a drain electrode, a data line, a signal line VDD, and a storage capacitor plate of the thin film transistor, and the gate layer pattern includes patterns such as a gate electrode of the thin film transistor and a gate line. In the present embodiment, the light-shielding layer can be made of a non-transparent material such as Al, Mo and Cu, and the gate layer pattern can be made of the transparent conductive material or the metal.

In an optional embodiment of the present disclosure, the active layer pattern includes the first semiconductor sub-pattern and the second active layer sub-pattern, wherein the second active layer sub-pattern is subjected to the conductive treatment, the source-drain layer pattern further includes the signal line connected to the anode, an overlapping area exists between the orthographic projection of the second active layer sub-pattern on the base substrate and the orthographic projection of the signal line on the base substrate; as shown in FIG. 3, the second active layer sub-pattern 103-3 is connected in parallel to the signal line 107-3 via the plurality of through holes; and double layer wirings are formed to reduce the impedance of the signal line.

In the related art, a gate metal layer and a source-drain metal layer are used to form the double-layer wiring of the signal line, and the thickness ratio of the gate metal layer and the source-drain metal layer is relatively large, which not only affects the pixel aperture opening rate, but also increases the segment gap in different areas of the display substrate. In the present embodiment, the double-layer wiring is formed by using the second active layer sub-pattern 103-3 which has been subjected to the conductive treatment, wherein the thickness of the second active layer sub-pattern 103-3 is generally 40-70 nm, the thickness thereof is relatively small, and the second active layer sub-pattern 103-3 is made of the transparent material such as IGZO. On the one hand, the segment gap of the different areas of the display substrate can be reduced, and on the other hand, the pixel aperture opening ratio can be improved.

In an optional embodiment of the present disclosure, when the second active layer sub-pattern and the signal line are used to form the double-layer wiring, a film layer such as the gate electrode layer and the gate insulating layer cannot be provided between the second active layer sub-pattern and the signal line; that is, the direct contact between the second active layer sub-pattern and the signal lines can reduce the segment gap of the different areas of the display substrate.

In an optional embodiment of the present disclosure, a gate layer pattern which is used for forming the double-layer wiring can still be made of metal, the source-drain layer pattern including the signal line connected to the anode, wherein the gate layer pattern includes the first gate layer sub-pattern and the second gate layer sub-pattern other than the first gate electrode layer sub-pattern, and an overlapping area exists between the first gate layer sub-pattern and the orthographic projection of the signal line on the base substrate; the first gate layer sub-pattern and the signal line are connected in parallel via the plurality of through holes, and the thickness of the first gate layer sub-pattern is less than the thickness of the second gate layer sub-pattern; and in the present embodiment, as shown in FIG. 2, when the first gate layer sub-pattern 105-1 is manufactured, the thickness of the first gate layer sub-pattern 105-1 is decreased, and the thinned first gate layer sub-pattern 105-1 and the signal line 107-3 are used to form the double-layer wiring, and the thickness of the thinned first gate layer sub-pattern 105-1 can be less than 400 nm, specifically, it can be 50 to 300 nm. In the double-layer wiring area, the thickness of the first gate layer is relatively small, so that the film thickness of the double-layer wiring area can be reduced, thereby reducing the film segment gap of the OLED display substrate.

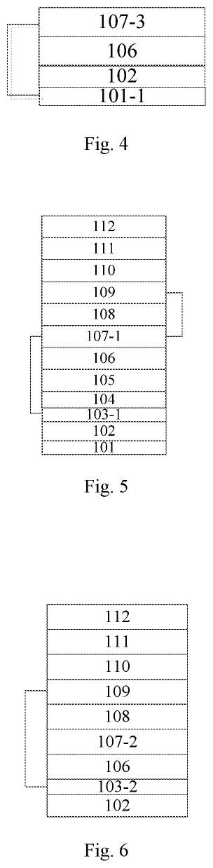

In an optional embodiment of the present disclosure, the source-drain layer pattern includes the signal line connected to the anode, the light-shielding layer includes a first light-shielding sub-pattern, an overlapping area exists between the first light-shielding sub-pattern and the orthographic projection of the signal line on the base substrate, and the first light-shielding sub-pattern is connected with the signal line in parallel via the plurality of through holes; in the present embodiment, as shown in FIG. 4, when patterning the light-shielding layer, a part of the light-shielding layer remains below the signal line 107-3 as the first light-shielding pattern 101-1; and the double-layer wiring is formed by using the first light-shielding pattern 101-1 and the signal line 107-3, wherein the thickness of the first light-shielding pattern is relatively small, typically several tens of nm, so that the film thickness of the double-layer wiring area can be reduced, thereby reducing the film segment gap of the OLED display substrate.

In an optional embodiment of the present disclosure, the active layer pattern includes a third active layer sub-pattern, wherein the third active layer sub-pattern is subjected to the conductive treatment, the source-drain layer pattern further includes a storage capacitor plate; an overlapping area exists between the orthographic projection of the third active layer sub-pattern on the base substrate and the orthographic projection of the storage capacitor plate on the base substrate; and the third active layer sub-pattern and the storage capacitor plate constitute a first storage capacitor of the OLED display substrate.

In optional embodiments of the present disclosure, the storage capacitor plate is made of an ITO or an IZO material.

In the present embodiment, a third active layer sub-pattern subjected to the conductive treatment is used to form the storage capacitor, instead of using the storage capacitor formed by the light-shielding layer and the storage capacitor plate, the third active layer sub-pattern is made of the transparent material such as IGZO, without affecting the pixel aperture opening ratio; furthermore, since it is not necessary to use the light-shielding layer and the storage capacitor plate to form the storage capacitor, the area of the light-shielding layer can be reduced, thereby facilitating the improvement of the pixel aperture opening ratio. In addition, the storage capacitor plate can also be made of a transparent conductive material such as ITO and IZO, so that the first storage capacitor does not block light, and the area of the light transmission area can be increased, thereby increasing the pixel aperture opening ratio.

In an optional embodiment of the present disclosure, an overlapping area exists between a orthographic projection of the anode on the base substrate and a orthographic projection of the storage capacitor plate on the base substrate, the storage capacitor plate and the anode constitute a second storage capacitor of the OLED display substrate. Since the anode can be made of the transparent conductive material, such as ITO and IZO, and the storage capacitor plate can also be made of the transparent conductive material, such as ITO and IZO, the second storage capacitor does not block light, and can increase the area of the light transmission area, thereby improving the pixel aperture opening ratio.

In an optional embodiment of the present disclosure, the active layer pattern includes the first semiconductor sub-pattern and the second active layer sub-pattern, wherein the first semiconductor sub-pattern is located in a channel area of the thin film transistor, and the light shielding layer is mainly used for shielding light irradiated to the first semiconductor sub-pattern. In order to increase the pixel aperture opening ratio, the orthographic projection of the light-shielding layer on the base substrate is located within the orthographic projection of the first semiconductor sub-pattern on the base substrate.

Embodiments of the present disclosure also provide the display device including the OLED display substrate as described above.

The display device includes, but is not limited to: a radio frequency unit, a network module, an audio output unit, an input unit, a sensor, a display unit, a user input unit, an interface unit, a memory, a processor, and a power supply, etc. Those skilled in the art should know that the configuration of the display device described above is not to be construed as limiting the display device, and that the display device can include more or fewer of the components described above, or some combinations of the components, or different arrangements of the components. In embodiments of the present disclosure, the display devices include, but are not limited to, displays, cell phones, tablets, televisions, wearable electronics, navigation display devices, and the like.

The display device can be: any product or component with a display function, such as a television, a display, a digital photo frame, a mobile phone, a tablet computer, wherein the display device further includes a flexible circuit board, a printed circuit board, and a back plate.

The embodiments of the present disclosure also provide a method for manufacturing the OLED display substrate, which is used for manufacturing the OLED display substrate as described above, the OLED display substrate includes a light-shielding layer, a buffer layer, an active layer pattern, a gate insulating layer, a gate layer pattern, and an interlayer insulating layer, a source-drain layer pattern, an anode, a light-emitting layer, and a cathode formed in turn on the substrate, wherein the source-drain layer pattern and/or the gate layer pattern are made of the transparent conductive material.

In the present embodiment, the source-drain layer pattern can be made of the transparent conductive material, or the gate layer pattern can be made of the transparent conductive material, or both the source-drain layer pattern and the gate layer pattern can be made of the transparent conductive material. Compared with using the non-transparent metal for manufacturing the source-drain layer pattern and/or the gate layer pattern, the metal wiring density can be greatly reduced, so that a top-emitting OLED display device or a bottom-emitting OLED display device with a high aperture opening ratio can be manufactured, and even a transparent display device can be formed.

The base substrate can be a rigid transparent substrate or a flexible transparent substrate, wherein the transparent conductive material can specifically be ITO or IZO. The source-drain layer pattern includes patterns such as a source electrode, a drain electrode, a data line, a signal line VDD, and a storage capacitor plate of the thin film transistor, and the gate layer pattern includes patterns such as a gate electrode of the thin film transistor and a gate line. In the present embodiment, the light-shielding layer can be made of a non-transparent material such as Al, Mo and Cu, and the gate layer pattern can be made of the transparent conductive material or the metal.

In one specific embodiment, the method for manufacturing the OLED display substrate can include the following steps:

step 1, forming the light-shielding layer on the substrate, patterning the light-shielding layer, and forming a pattern 101 of the light-shielding layer on the substrate, wherein the light-shielding layer is used for shielding the active layer of the thin film transistor, therefore, the pattern 101 of the light-shielding layer can exist only in the thin film transistor area shown in FIG. 5;

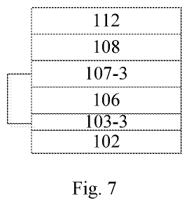

forming a buffer layer 102, and as shown in FIGS. 5-7, there is a buffer layer 102 in the thin film transistor area, the storage capacitor area, and the double-layer wiring area;

step 2, forming a layer of IGZO material layer on the substrate, patterning the IGZO material layer, and forming the first semiconductor sub-pattern 103-1 in the channel area of the thin film transistor as shown in FIGS. 5-7; forming a third active layer sub-pattern 103-2 in the storage capacitor area, and forming a second active layer sub-pattern 103-3 in the double-layer wiring area;

step 3, forming the gate insulating layer and the gate electrode layer, patterning the gate insulating layer and the gate electrode layer, as shown in FIG. 5, forming the gate insulating layer pattern 104 and the gate layer pattern 105, wherein the gate insulating layer pattern 104 and the gate layer pattern 105 do not exist in the storage capacitor area and the double-layer wiring area;

specifically, the gate insulating layer and the gate electrode layer can be patterned by a dry etching method;

step 4, taking the gate layer pattern 105 as a mask, performing the conductive treatment on the second active layer sub-pattern 103-3 and the third active layer sub-pattern 103-2 by using He or NH3 plasma radicals so that the first semiconductor sub-pattern 103-1 covered by the gate layer pattern 105 is not subjected to the conductive treatment and retains semiconductor characteristics as the active layer at the channel of the thin film transistor, the second active layer sub-pattern 103-3 and the third active layer sub-pattern 103-2 which are not covered by the gate layer pattern 105 are subjected to the conductive treatment to obtain the conductor characteristics;

step 5, forming an interlayer insulating layer 106, and as shown in FIGS. 5-7, an interlayer insulating layer 106 is provided in the thin film transistor area, the storage capacitor area and the double-layer wiring area;

Step 6, forming a transparent conductive material layer, patterning the transparent conductive material layer to form a source-drain 107-1 in the thin film transistor area, forming a storage capacitor plate 107-2 in the storage capacitor area, and forming a signal line 107-3 in the double-layer wiring area; wherein the signal line 107-3 can be connected to the second active layer sub-pattern 103-3 via the through holes to form the double-layer wiring; in the storage capacitor area, wherein the storage capacitor plate 107-2 and the third active layer sub-pattern 103-2 form the storage capacitor;

step 7, forming a protective insulating layer 108, and as shown in FIGS. 5-7, the protective insulating layer 108 do exist in the thin film transistor area, the storage capacitor area, and the double-layer wiring area;

step 8, forming a transparent conductive material layer, as shown in FIGS. 5-7, patterning the transparent conductive material layer to form an anode 109 in the storage capacitor area of the thin film transistor area, wherein, in the thin film transistor area, the anode 109 is connected to the drain electrode of the thin film transistor via the through holes, and in the storage capacitor area, the anode 109 and the storage capacitor plate 107-2 constitute the storage capacitor;

step 9, forming light-emitting layer 110 which displays red, green and blue (RGB) colors respectively by using the ink-jet printing technique described above on the anode 109;

step 10, forming a transparent cathode 111 on the light-emitting layer 110; and

step 11, forming an encapsulation layer 112 on the transparent cathode 111.

The OLED display substrate of the present embodiment can be obtained through the above-mentioned steps.

The light-emitting layer 110 can be formed by an evaporation method. The anode 109 can use the transparent material or the non-transparent material, and when the anode 109 uses the non-transparent material such as an Al/ITO stack structure, a top-emission OLED display device with a high aperture opening ratio can be formed; Ag can also be used to form the cathode 111 and then form a bottom-emitting OLED display device with a high aperture opening ratio.

In the various method in the embodiments of the present disclosure, the sequence number of each step cannot be used to define the order of each step, and for a person of ordinary skill in the art, without involving any inventive effort, it is also within the scope of the present disclosure to change the order of each step.

It should be understood that each of the embodiments described in the specification is intended to be presented in an enabling manner, similar elements can be referenced throughout the various embodiments, and each of the embodiments is intended to cover variations from the other embodiments. Particularly, the system embodiments are similar to product embodiments, and therefore are described briefly. For a related part, references can be made to some descriptions in the product embodiments.

Unless defined otherwise, technical or scientific terms used in the present disclosure should have the ordinary meaning as understood by one of ordinary skill in the art to which the disclosure belongs. As used in this disclosure, the terms “first, second” and the like do not denote any order, quantity, or importance, but rather are used to distinguish one element from another. The word “include” or “comprise” or the like, means that the element or component preceded by the word is inclusive of the element or component listed after the word and its equivalents, and does not exclude other elements or components. Similar terms such as “connect” or “connected” are not limited to physical or mechanical connections, but may include electrical connections, whether direct or indirect. “Upper, lower, left, right” and the like are used merely to denote relative positional relationships, which may change accordingly when the absolute position of the object being described changes.

It can be understood that when an element such as a layer, film, area or substrate is referred to as being “upper” or “lower” located on the other element, it can be “directly upper” or “lower” located on the other element or intervening elements may be present.

In the description of the embodiments above, particular features, structures, materials, or characteristics can be combined in any suitable manner in any one or more embodiments or examples.

The above embodiments are merely specific implementation modes of the present disclosure, but the scope of protection of the present disclosure is not limited thereto, and any modification and substitution be apparent to those skilled in the art without departing from the technical scope of the present disclosure shall covered by the scope protection of the present disclosure. Therefore, the scope of protection of the disclosure shall be subject to the scope of protection of the claims.

1. An OLED display substrate, comprising an active layer pattern, a gate layer pattern, a source-drain layer pattern, an anode, a light-emitting layer and a cathode which are arranged in turn on a base substrate, wherein the source-drain layer pattern comprises a source electrode and a drain electrode of a thin film transistor and a data line, the gate layer pattern comprises a gate electrode of the thin film transistor and a gate line, wherein the source-drain layer pattern and/or the gate layer pattern are made of a transparent conductive material.

2. The OLED display substrate according to claim 1, wherein the active layer pattern comprises a first semiconductor sub-pattern and a second active layer sub-pattern, the second active layer sub-pattern being subjected to a conductive treatment, the source-drain electrode layer pattern further comprises a signal line connected to the anode, and an overlapping area exists between an orthographic projection of the second active layer sub-pattern on the base substrate and an orthographic projection of the signal line on the base substrate; the second active layer sub-pattern is connected to the signal line in parallel through a plurality of through holes.

3. The OLED display substrate according to claim 2, wherein the second active layer sub-pattern is in direct contact with the signal line.

4. The OLED display substrate according to claim 1 or 2, wherein the active layer pattern comprises a third active layer sub-pattern, the third active layer sub-pattern is subjected to a conductive treatment, and the source-drain layer pattern further comprises a storage capacitor plate, an overlapping area exists between an orthographic projection of the third active layer sub-pattern on the base substrate and an orthographic projection of the storage capacitor plate on the base substrate; and the third active layer sub-pattern and the storage capacitor plate constitute a first storage capacitor of the OLED display substrate.

5. The OLED display substrate according to claim 4, wherein the storage capacitor plate is made of ITO or an IZO material.

6. The OLED display substrate according to claim 4, wherein an overlapping area exists between an orthographic projection of the anode on the base substrate and an orthographic projection of the storage capacitor plate on the base substrate, the storage capacitor plate and the anode constitute a second storage capacitor of the OLED display substrate.

7. The OLED display substrate according to claim 1, wherein the active layer pattern comprises a first semiconductor sub-pattern and a second active layer sub-pattern, an orthographic projection of a light-shielding layer on the base substrate is located within the orthographic projection of the first semiconductor sub-pattern on the base substrate.

8. The OLED display substrate according to claim 1, wherein the source-drain layer pattern comprises the signal line connected to the anode, and the gate layer pattern comprises a first gate layer sub-pattern and a second gate layer sub-pattern other than the first gate layer sub-pattern, an overlapping area exists between the orthographic projection of the first gate layer sub-pattern and the orthographic projection of the signal line on the base substrate, and the first gate layer sub-pattern and the signal line are connected in parallel via the plurality of through holes, and the thickness of the first gate layer sub-pattern is less than the thickness of the second gate layer sub-pattern.

9. The OLED display substrate according to claim 1, wherein the source-drain layer pattern comprises the signal line connected to the anode, the light-shielding layer comprises a first light-shielding sub-pattern, an overlapping area exists between the orthographic projection of the first light-shielding sub-pattern and the orthographic projection of the signal line on the base substrate, and the first light-shielding sub-pattern and the signal line are connected in parallel through a plurality of through holes.

10. A display device, comprising the OLED display substrate according to claim 1.

11. A method for manufacturing an OLED display substrate according to claim 1, comprising forming an active layer pattern, a gate layer pattern, a source-drain layer pattern, an anode, a light-emitting layer, and a cathode arranged in turn on the base substrate, wherein the source-drain layer pattern and/or the gate layer pattern are made of a transparent conductive material.

12. The method according to claim 11, before forming the active layer pattern, further comprising:
forming a light-shielding layer on the base substrate; and
forming a buffer layer.

13. The method according to claim 12, further comprising:
forming the active layer pattern on the base substrate, comprising forming the first semiconductor sub-pattern, the second active layer sub-pattern, and a third active layer sub-pattern;
forming a gate insulating layer pattern and a gate layer pattern;
performing the conductive treatment to the second active layer sub-pattern and the third active layer sub-pattern by using the gate layer pattern as a mask;
forming an interlayer insulating layer;
patterning a layer of transparent conductive material to form the source-drain, the storage capacitor plate and the signal line; and
forming a protective insulating layer.

14. The method according to claim 13, further comprising:
forming the anode by patterning the layer of transparent conductive material;
forming the light-emitting layer on the anode by using an ink-jet printing technique;
forming a transparent cathode on the light-emitting layer; and
forming an encapsulation layer on the transparent cathode.
